(19) United States
(12) Patent Application Publication
(10) Pub. No.: US 2026/0012267 A1
(43) Pub. Date: Jan. 8, 2026

(54) SYSTEM AND METHOD FOR MONITORING VSWR IN RADIO SYSTEM

(71) Applicant: JIO PLATFORMS LIMITED, Ahmedabad (IN)

(72) Inventors: Pradeep Kumar BHATNAGAR, Navi Mumbai (IN); Deepak GUPTA, Navi Mumbai (IN); Nekiram KHOSYA, Dombivali (E) (IN); Satyajit SAHOO, Navi Mumbai (IN); Aayush BHATNAGAR, Navi Mumbai (IN)

(73) Assignee: JIO PLATFORMS LIMITED, Ahmedabad (IN)

(21) Appl. No.: 18/992,310

(22) PCT Filed: May 22, 2024
(86) PCT No.: PCT/IN2024/050598

§ 371 Date: Jan. 8, 2025

(30) Foreign Application Priority Data
Jun. 27, 2023 (IN) 202321043068

(51) Int. Cl. H04B 17/10; G01R 27/06; H04B 1/04

(52) U.S. Cl. CPC H04B 17/103; G01R 27/06; H04B 1/0475; H04B 2001/0425

(57) ABSTRACT

The present disclosure provides a system and a method for monitoring Voltage Standing Wave Ratio (VSWR) in a radio system. The present disclosure monitors Radio Frequency (RF) chain performance and VSWR-related issues in a cost-effective manner. The present disclosure enables real-time monitoring of VSWR levels without a need of any external measurement device. The present disclosure continuously analyses the reflected power and impedance matching within the radio system. The present disclosure detects and identifies potential VSWR anomalies that may lead to signal degradation or equipment failure in advance. The present disclosure improves performance and reliability of the radio system. The present disclosure ensures optimal radio system performance in a cost-effective manner. The present disclosure reduces operating expenses or expenditure (OPEX) cost and failure turnaround time of operators.

### RESERVATION OF RIGHTS

A portion of the disclosure of this patent document contains material which is subject to intellectual property rights such as, but are not limited to, copyright, design, trademark, integrated circuit (IC) layout design, and/or trade dress protection, belonging to Jio Platforms Limited (JPL) or its affiliates (herein after referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### TECHNICAL FIELD

The present disclosure relates to a field of monitoring Radio Frequency (RF) chain performance and Voltage Standing Wave Ratio (VSWR)-related issues, and specifically to a system and a method for monitoring VSWR in a radio system.

### BACKGROUND

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

In general, a typical Fifth-Generation (5G) New Radio (NR) system includes a transmit chain(s) with a link budget such that a particular output power is radiated as per region specific regulation norms. Higher transmit power than expected power may cause saturation of power amplifier leading to non-linearity, overall signal degradation and non-compliance with regional telecom regulatory laws. Similarly, low transmit power may lead to lower coverage and poor user experience. When no power is reflected at an antenna port, Voltage Standing Wave Ratio (VSWR) may be closed to its ideal value of one or reflection coefficient near to zero. Opened or loose port connections at the antenna or failure of components at output of a power amplifier may lead to poor VSWR. Thereby, leading to degradation of optimal radio system performance and increase in operational expenditure (OPEX) cost and failure turnaround time of the operators.

There is, therefore, a need in the art to improve state of enabling proactive monitoring and early detection of VSWR-related issues to ensure optimal radio system performance in a cost-effective manner by overcoming the deficiencies of the prior arts.

### SUMMARY

In an exemplary embodiment, a method for performing monitoring of voltage standing wave ratio (VSWR) in a radio system is described. The method comprises capturing a feedback digital pre-distortion (DPD) power from a DPD application at an application specific integrated circuit (ASIC)/a digital front end (DFE). The method further comprises calculating a transmit power at an antenna port by adding a transmit power factor and the feedback DPD power. The method comprises reading a radio frequency (RF) power detector voltage output of a power detector circuitry received via an on-board coupler and a pi-PAD. The method further comprises converting the RF power detector voltage output into an ADC value by an analog to digital converter (ADC). The method comprises detecting whether the ADC value is valid. The method further comprises on detecting that the ADC value is valid, calculating power detected at the power detector circuitry. The method comprises on detecting that the ADC value is not valid, reading the radio frequency (RF) power detector voltage output at the power detector circuitry. The method comprises calculating a reflected power at the antenna port by adding a reflected power factor and the power detected at the power detector circuitry. The method comprises calculating a return loss at the antenna port and detecting whether the return loss is equal to or less than zero. The method comprises on detecting that the return loss is equal to or less than zero, calculating a reflection coefficient and the VSWR.

In some embodiment, the return loss is difference between the transmitted power and the reflected power at the antenna port.

In some embodiment, the DPD application is configured to characterize distortion by analyzing output of a power amplifier (PA) and alter an input signal to the PA.

In some embodiment, on detecting that the return loss is not equal to or less than zero, the method comprising performing of monitoring of VSWR.

In some embodiment, the transmit power calculation factor is calculated for each of plurality of transmit chains based on difference between the DPD feedback power received at the ADC of the ASIC/DFE and the transmitted power received at the antenna port.

In another exemplary embodiment, a system for performing monitoring of voltage standing wave ratio (VSWR) in a radio system is described. The system comprises an application specific integrated circuit (ASIC)/a digital front end (DFE), a transceiver chain, a cavity filter, and a radio frequency (RF) antenna port. The ASIC/DFE having a digital pre-distortion (DPD) application is configured to capture a feedback DPD power. The RF antenna port is configured to calculate a transmit power by adding a transmit power factor and the feedback DPD power. A power detector circuitry of the transceiver chain is configured to read a radio frequency (RF) power detector voltage output received via an on-board coupler and a pi-PAD. An analog to digital converter (ADC) of the transceiver chain is configured to convert the RF power detector voltage output into an analog value. The ASIC/DFE is configured to detect whether the ADC value is valid. On detecting that the ADC value is valid, the ASIC/DFE is configured to calculate power detected at the power detector circuitry. On detecting that the ADC value is not valid, the power detector circuitry configured to read the radio frequency (RF) power detector voltage output. The ASIC/DFE is configured to calculate a reflected power by adding a reflected power factor and the power detected at the power detector circuitry. The ASIC/DFE configured to calculate a return loss and detect whether the return loss is equal to or less than zero. On detecting that the return loss is equal to or less than zero, the ASIC/DFE is configured to calculate a reflection coefficient and the VSWR.

In some embodiment, the return loss is difference between the transmitted power and the reflected power at the antenna port.

In some embodiment, on detecting that the return loss is not equal to or less than zero, the system configured to perform monitoring of VSWR.

In some embodiment, the transmit power calculation factor is calculated for each of plurality of transmit chains based on difference between the DPD feedback power received at the ADC of the ASIC/DFE and the transmitted power received at the antenna port.

In some embodiment, the transceiver chain comprises a transmission chain, a feedback chain, and a receiver chain. The transmission chain comprises a first filter, a first digital step attenuator (DSA), a pre-driver, a power amplifier, a coupler and a circulator. The feedback chain comprises a filter and a first Pi-PAD.

The receiver chain comprises a second PI-PAD, a single pole double throw (SPDT), a gain block, a second DSA, a second filter, a third SPDT, a low noise amplifier and the on-board coupler.

In yet another exemplary embodiment, an apparatus for performing monitoring of voltage standing wave ratio (VSWR) is described. The apparatus comprising an on-board coupler, a radio frequency (RF) power detector, and an analog-to-digital converter (ADC). The on-board coupler configured to receive power reflected at an antenna port. The RF power detector configured to calculate received power via the on-board coupler. The RF power detector configured to translate the calculated power into analog voltage. The ADC configured to convert the analog voltage to digital voltage signal. The ADC configured to send the digital voltage signal to an application specific integrated circuit (ASIC)/a digital front end (DFE).

In some embodiment, calculating a transmitted power at the antenna port comprising a signal analyser configured to measure a digital pre-distortion (DPD) feedback power. The signal analyser configured to calculate transmit power calculation factor for each of plurality of transmit chains based on difference between the DPD feedback power received at an ADC of the ASIC/DFE and the transmitted power received at the antenna port. The signal analyser configured to calculate the transmitted power at the antenna port based on the DPD power and the transmit power calculation factor.

In some embodiment, calculating a reflected power at the antenna port comprising the signal analyser configured to calculate reflected power calculation factor for each of plurality of receive chains based on insertion loss between the antenna port to the RF power detector. The signal analyser configured to calculate the reflected power at the antenna power based on the received power at the RF power detector and the reflected power calculation factor.

In some embodiment, calculating a return loss at the antenna port comprising the ASIC/the DFE configured to calculate the return loss at the antenna port is difference between the reflected power and the transmitted power at the antenna port.

In some embodiment, calculating VSWR comprising the ASIC/the DFE configured to calculate a reflection coefficient based on the return loss at the antenna port and the ASIC/the DFE configured to calculate VSWR based on the reflection coefficient.

### OBJECTS OF THE PRESENT DISCLOSURE

It is an object of the present disclosure to monitor Radio Frequency (RF) chain performance and Voltage Standing Wave Ratio (VSWR)-related issues in a cost-effective manner.

It is an object of the present disclosure to enable real-time monitoring of VSWR levels without a need of any external measurement device.

It is an object of the present disclosure to continuously analyse the reflected power and impedance matching within the radio system.

It is an object of the present disclosure to detect and identify potential VSWR anomalies that may lead to signal degradation or equipment failure in advance.

It is an object of the present disclosure to improve performance and reliability of the radio system.

It is an object of the present disclosure to ensure optimal radio system performance in a cost-effective manner.

It is an object of the present disclosure to reduce operating expenses or expenditure (OPEX) cost and failure turnaround time of operators.

### BRIEF DESCRIPTION OF THE DRAWINGS

In the figures, similar components and/or features may have the same reference label. Further, various components of the same type may be distinguished by following the reference label with a second label that distinguishes among the similar components. If only the first reference label is used in the specification, the description is applicable to any one of the similar components having the same first reference label irrespective of the second reference label.

The diagrams are for illustration only, which thus is not a limitation of the present disclosure, and wherein:

FIG. 1 illustrates an exemplary network architecture (100) in which or with which embodiments of the present disclosure may be implemented.

FIG. 2 illustrates an exemplary architecture (200) of a Voltage Standing Wave Ratio (VSWR) monitoring system (108), in accordance with an embodiment of the present disclosure.

FIG. 3 illustrates an exemplary graphical representation (300) of generic Radio Frequency (RF) power detector response curve, in accordance with an embodiment of the present disclosure.

FIG. 4 illustrates an exemplary flow chart (400) of VSWR calculating process, in accordance with an embodiment of the present disclosure.

FIG. 5 illustrates an exemplary computer system (500) in which or with which embodiments of the present disclosure may be implemented.

### DETAILED DESCRIPTION

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

Generally, a typical Fifth-Generation (5G) New Radio (NR) system includes a transmit chain(s) with a link budget such that a particular output power is radiated as per region specific regulation norms. Higher transmit power than expected power may cause saturation of power amplifier leading to non-linearity, overall signal degradation and non-compliance with regional telecom regulatory laws. Similarly, low transmit power may lead to lower coverage and poor user experience. When no power is reflected at an antenna port, Voltage Standing Wave Ratio (VSWR) may be closed to its ideal value of one or reflection coefficient near to zero. Opened or loose port connections at the antenna or failure of components at output of a power amplifier may lead to poor VSWR. Thereby, leading to degradation of optimal radio system performance and increase in operational expenditure (OPEX) cost and failure turnaround time of the operators.

The proposed system may combine advanced signal processing along with unique hardware system design that enables real-time monitoring of VSWR levels without a need of any external measurement device. The proposed system may use Electromagnetic (EM) simulated micro strip line-based on-board designed couplers, power detectors and Analog to Digital Converters (ADCs) to monitor reverse power and calculate VSWR at an antenna port without need of any external measurement device. By continuously analysing the reflected power and impedance matching within the radio system, the proposed system may detect and identify potential VSWR anomalies that may lead to signal degradation or equipment failure in advance. The proposed system may improve 5G radio system performance and reliability. The proposed system may ensure optimal radio system performance in a cost-effective manner. The proposed system may reduce operating expenses or expenditure (OPEX) cost and failure turnaround time of the operators.

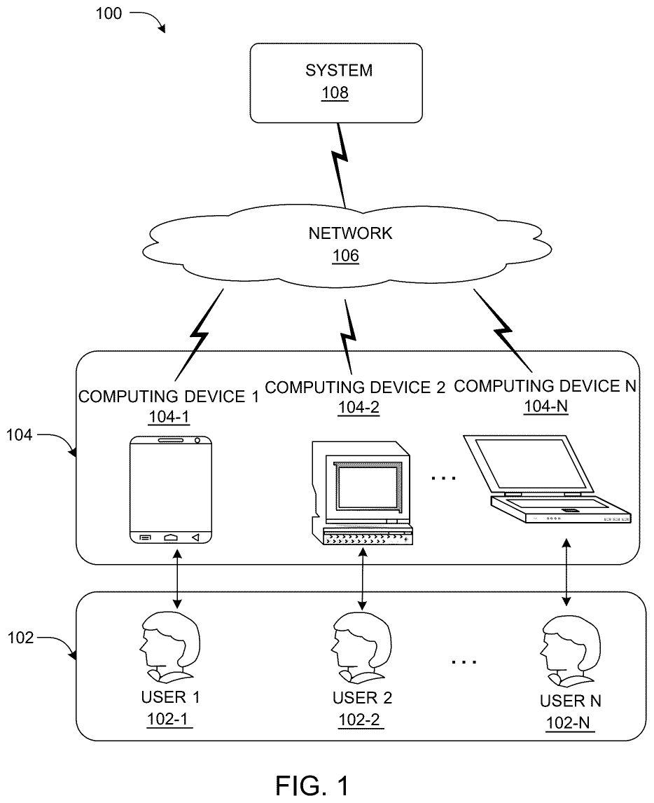

The various embodiments of the present disclosure will be explained in detail with reference to FIGS. 1 to 5.

FIG. 1 illustrates an exemplary network architecture (100) in which or with which embodiments of the present disclosure may be implemented.

Referring to FIG. 1, the network architecture (100) may include one or more user equipments (104-1, 104-2 . . . 104-N) associated with one or more users (102-1, 102-2 . . . 102-N) in an environment. A person of ordinary skill in the art will understand that one or more users (102-1, 102-2 . . . 102-N) may be individually referred to as the user (102) and collectively referred to as the users (102). Similarly, a person of ordinary skill in the art will understand that one or more user equipments (104-1, 104-2 . . . 104-N) may be individually referred to as the user equipment (104) and collectively referred to as the user equipment (104). A person of ordinary skill in the art will appreciate that the terms “computing device(s)” and “user equipment” may be used interchangeably throughout the disclosure. Although three user equipments (104) are depicted in FIG. 1, however any number of the user equipments (104) may be included without departing from the scope of the ongoing description.

In an embodiment, the user equipment (104) may include smart devices operating in a smart environment, for example, an Internet of Things (IoT) system. In such an embodiment, the user equipment (104) may include, but is not limited to, smart phones, smart watches, smart sensors (e.g., mechanical, thermal, electrical, magnetic, etc.), networked appliances, networked peripheral devices, networked lighting system, communication devices, networked vehicle accessories, networked vehicular devices, smart accessories, tablets, smart television (TV), computers, smart security system, smart home system, other devices for monitoring or interacting with or for the users (102) and/or entities, or any combination thereof. A person of ordinary skill in the art will appreciate that the user equipment (104) may include, but is not limited to, intelligent, multi-sensing, network-connected devices, that can integrate seamlessly with each other and/or with a central server or a cloud-computing system or any other device that is network-connected.

In an embodiment, the user equipment (104) may include, but is not limited to, a handheld wireless communication device (e.g., a mobile phone, a smart phone, a phablet device, and so on), a wearable computer device (e.g., a head-mounted display computer device, a head-mounted camera device, a wristwatch computer device, and so on), a Global Positioning System (GPS) device, a laptop computer, a tablet computer, or another type of portable computer, a media playing device, a portable gaming system, and/or any other type of computer device with wireless communication capabilities, and the like. In an embodiment, the user equipment (104) may include, but is not limited to, any electrical, electronic, electro-mechanical, or an equipment, or a combination of one or more of the above devices such as virtual reality (VR) devices, augmented reality (AR) devices, laptop, a general-purpose computer, desktop, personal digital assistant, tablet computer, mainframe computer, or any other computing device, wherein the user equipment (104) may include one or more in-built or externally coupled accessories including, but not limited to, a visual aid device such as a camera, an audio aid, a microphone, a keyboard, and input devices for receiving input from the user (102) or the entity such as touch pad, touch enabled screen, electronic pen, and the like. A person of ordinary skill in the art will appreciate that the user equipment (104) may not be restricted to the mentioned devices and various other devices may be used.

Referring to FIG. 1, the user equipment (104) may communicate with a system (108), for example, a VSWR monitoring system, through a network (106). In an embodiment, the network (106) may include at least one of a Fifth-Generation (5G) network, a Sixth-Generation (6G) network, or the like. The network (106) may enable the user equipment (104) to communicate with other devices in the network architecture (100) and/or with the system (108). The network (106) may include a wireless card or some other transceiver connection to facilitate this communication. In another embodiment, the network (106) may be implemented as, or include any of a variety of different communication technologies such as a wide area network (WAN), a local area network (LAN), a wireless network, a mobile network, a Virtual Private Network (VPN), the Internet, the Public Switched Telephone Network (PSTN), or the like.

In accordance with embodiments of the present disclosure, the system (108) may be designed and configured for enabling real-time monitoring of VSWR levels without the need of any external measurement device. The proposed system may use EM simulated micro strip line-based on-board designed couplers, power detectors and ADCs to monitor reverse power and calculate VSWR at an antenna port without need of any external measurement device. The system (108) may improve 5G radio system performance and reliability by monitoring high, low transmit power, and chain failure in the radio system. The system (108) may reduce losses and reflections occurring at an output port of a power amplifier till an antenna port. Thereby, ensuring that maximum power is radiated out of an antenna and providing a valuable tool for radio operators and technicians in ensuring optimal radio system performance in a cost-effective manner. The system (108) may reduce OPEX cost and failure turnaround time of the operators.

Although FIG. 1 shows exemplary components of the network architecture (100), in other embodiments, the network architecture (100) may include fewer components, different components, differently arranged components, or additional functional components than depicted in FIG. 1. Additionally, or alternatively, one or more components of the network architecture (100) may perform functions described as being performed by one or more other components of the network architecture (100).

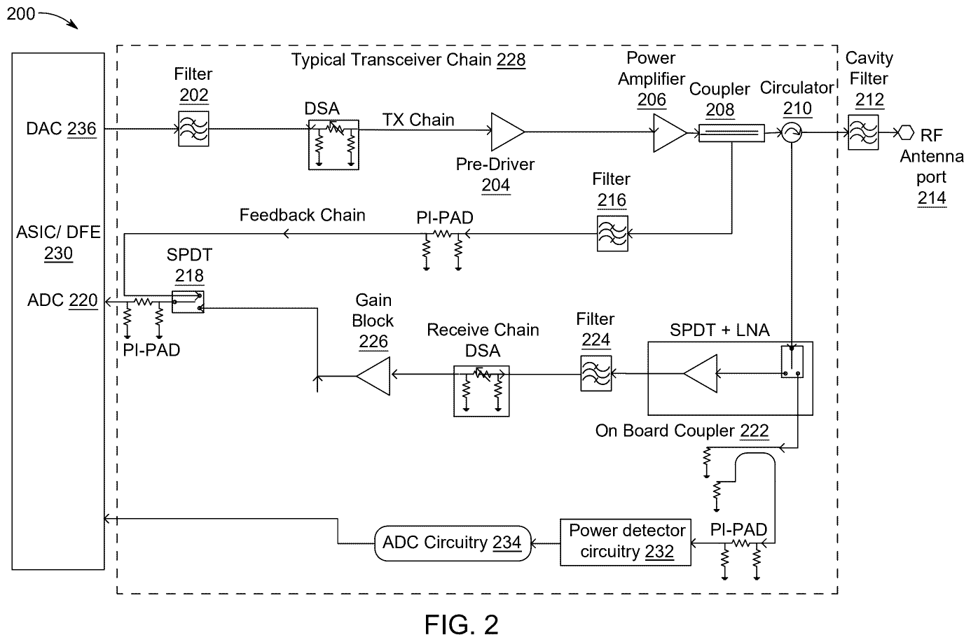

FIG. 2 illustrates an exemplary architecture (200) of a VSWR monitoring system (108), in accordance with an embodiment of the present disclosure.

In an aspect, the voltage standing wave ratio (VSWR) is an indication of the amount of mismatch between an antenna and a feed line connecting to the antenna. The VSWR may indicate the amount of power that can be safely delivered to an antenna without damaging it.

With respect to FIG. 2, the cost-effective VSWR monitoring system (108) may include an Application Specific Integrated Circuits/Digital Front End (ASIC/DFE), a transceiver chain, a cavity filter and a RF antenna port. The transceiver chain may include a transmission chain, a feedback chain, and a receiver chain. The transmission chain may include a filter (202), a pre-driver (204), a Power Amplifier (PA) (206), a coupler (208), a circulator (210), the cavity filter (212), the Radio Frequency (RF) antenna port (214), and a Digital to Analog converter (DAC) (236). The feedback chain may include a filter (216), a Single Pole Double Throw (SPDT) switch (218), and a PI-PAD. The SPDT may be connected to the ADC (220). The receiver chain may include an on-board coupler (222), a filter (224) and a gain block (226) and may be connected to the ADC (220). The transmission chain may include a digital step attenuator (DSA) and DSA for the receive (RX) chain. In an aspect, RF digital step attenuator (DSA) is a device that is used to apply a controlled amount of attenuation to an RF signal. The amount of attenuation is digitally controlled.

The single pole double throw (SPDT) is common terminal on the switch where the voltage and current is applied and that voltage and current can be either directed to the normally open or normally closed terminal.

The PI-PAD attenuator is used to reduce the level of a signal. The PI-PAD attenuator may also refer to as pads due to their effect of padding down a signal by analogy with acoustics.

The digital-to-analog converter (DAC) is a device that converts digital audio information (comprised of a series of 0s and 1s) into analog signals.

The cavity filter is type of RF filter that operates on the principle of resonance. The resonator oscillates with higher amplitude at a specific set of frequencies, called resonant frequencies. When an RF signal passes through the cavity filter, a resonator acts as a band-pass filter and passes RF signals at particular frequencies (i.e., resonant frequencies) while blocking other nearby frequencies.

The power amplifier is used to raise the power level of input signal. It is required to deliver a large amount of power and has to handle large current.

In an embodiment, the on-board coupler (222) and the ADC (220) may monitor reverse power and VSWR at the antenna port (214). In an aspect, an analog to digital converter (ADC) may work by sampling the value of the input at discrete intervals in time.

The ASIC/DFE (230) may include a Digital Pre-distortion (DPD) application. Every DPD application may seek to characterize distortion by analysing the PA output and alter the input signal so that the PA output may be ideal as possible. The VSWR monitoring system (108) may use transmitted and feedback power at DPD application along with power detected by RF power detector circuitry (232) to calculate VSWR.

In an aspect, the digital front end (DFE) may include components that perform digital signal conditioning to convert the 3GPP-defined baseband signal to a conditioned signal that compensates for inaccuracies in the analog transmit chain.

In an aspect, Digital Pre-Distortion (DPD) is one of the most fundamental building blocks in communication systems. The DPD increases the efficiency of power amplifiers (PA). The DPD may apply inverse distortion, using a pre-distorter, at the input signal of the PA to cancel the distortion generated by the PA.

The VSWR monitoring system (108) may calculate VSWR in following steps:

Step 1: Calculate power transmitted at the antenna port (214): For calculating power transmitted at the antenna port (214) from the DPD feedback power (Fb_{dpd,i}), the VSWR monitoring system (108) may determine transmit power calculation factors (Xᵢ) for each chain. The transmit power calculation factors (Xᵢ) may be determined on a golden calibrated radio for each of its chain by finding out difference between DPD feedback power received at the ADC (220) of ASIC and actual transmitted power received at the antenna port (214) measured using a signal analyser. The signal analyser may be part of the transceiver chain.

The transmit power calculation factors (Xᵢ) may be used to calculate the output transmit power for all calibrated radio units of same SKU2 (stock keeping unit).

Transmit power at the antenna output may be calculated using the below equation:

$${P}_{Fw \_ Ant , i} = {X}_{i} + F {b}_{dpd , i} \qquad ( 1 )$$

where Xᵢ is a factor for transmit power calculations for i th chain, and
Fb_{dpd,i} is feedback power received at DPD Application for i th chain.

Step 2: Calculate power reflected at the antenna port (214): To calculate the power reflected at the antenna port (214), the VSWR monitoring system (108) may calculate the power received at power detected and add factor for reflected power calculation.

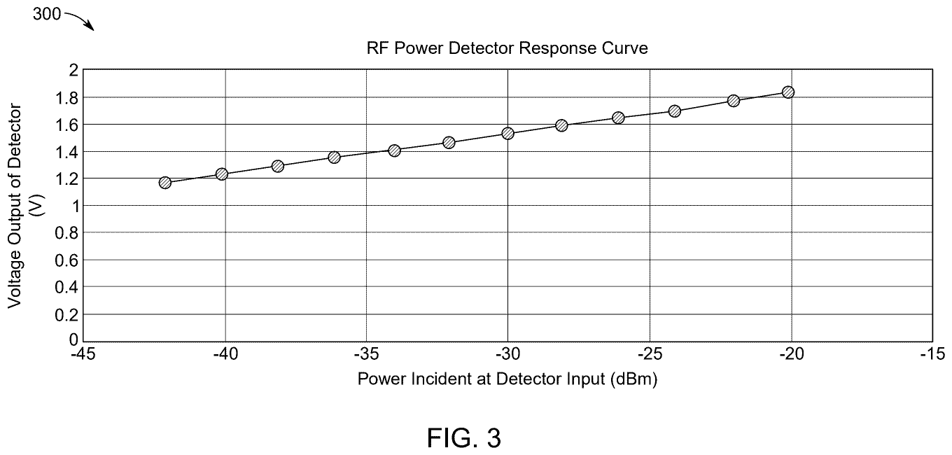

A RF power detector (232) may translate the power detected at its input to analog voltage at its output. This may be linear within device's acceptable dynamic range. Example of the linear response curve of a typical RF power detector (232) may be given in FIG. 3. The analog voltage may be converted to digital signal by using an on-board ADC. The digital signal may be received by a general-purpose Input/Output (IO) pin of the ASIC (230).

The linear response may be mathematically modelled as:

$$y = mx + c \qquad ( 2 )$$

where y=voltage at RF detector output which in turn is received by ADC,
x=RF Power received at RF detector input,
m=slope of the curve,
c=y axis intercept at x=0

Hence, RF power received (P_{det,i}) at detector input for i-th chain may be calculated as:

$$x = ( y - c ) / m \qquad ( 3 )$$

Also, the fixed insertion loss between the antenna port (214) to the RF detector input may be calculated theoretically for each chain. This may be the factor for reflected power calculations and may be denoted henceforth as Zᵢ for i-th chain.

Reflected power at the antenna port (214) for i-th chain may be calculated as:

$${P}_{Rv \_ Ant , i} = {P}_{det , i} + {Z}_{i} \qquad ( 4 )$$

Step 3: Calculate return loss at the antenna port (214): Return loss at the antenna port (214) of i-th chain may be the difference between the reflected and transmitted power at the antenna port (214), which may be calculated as:

$${RL}_{i} = {P}_{{Rv}_{Ant} , i} - {P}_{{Fw}_{Ant} , i} \qquad ( 5 )$$

Step 4: Calculate VSWR: The VSWR may be calculated as follows:

Reflection Coefficient,Tauᵢ=10\hat{ }(RLᵢ/20) (6)

$$Voltage Standing Wave Ratio , {VSWR}_{i} = \frac{( 1 + {Tau}_{i} )}{( 1 - {Tau}_{i} )} \qquad ( 7 )$$

FIG. 3 illustrates an exemplary graphical representation (300) of generic RF power detector response curve, in accordance with an embodiment of the present disclosure.

With respect to FIG. 3, a RF power detector may convert the power detected at its input to analog voltage at its output. The conversion of power may be linear within device's acceptable dynamic range. Example of the linear response curve of the RF power detector is depicted in FIG. 3. The analog voltage may be converted to digital signal by using an on board ADC. The digital signal may be received by a general-purpose IO pin of the ASIC.

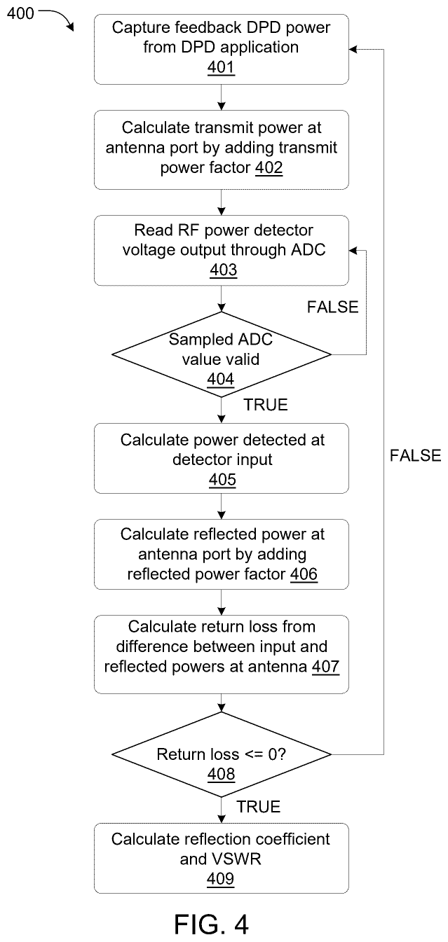

FIG. 4 illustrates an exemplary flow chart (400) of VSWR calculating process, in accordance with an embodiment of the present disclosure.

With respect to FIG. 4, at 401, feedback DPD power may be captured from a DPD application.
At 402, transmit power at the antenna port may be calculated by adding a transmit power factor.
At 403, upon calculation of the transmit power at the antenna port, RF power detector voltage output through the ADC may be read.
At 404, the process may determine whether the sampled ADC value is valid or not. If the sampled ADC value is not valid, step 403 may be continued.
At 405, if the sampled ADC value is valid, the power detected at the RF power detector input may be calculated.
At 406, based on the calculation of the power detected at the RF power detector input, the reflected power at the antenna port may be calculated by adding the reflected power factor.
At 407, the reflected power values may be used to calculate the return loss from a difference between the input power and the reflected power at the antenna.
At 408, the process may determine whether the return loss is less than or equal to 0. If the return loss is greater than 0, the process may proceed with step 401.
At 409, reflection coefficient and VSWR may be calculated based on the return loss value.

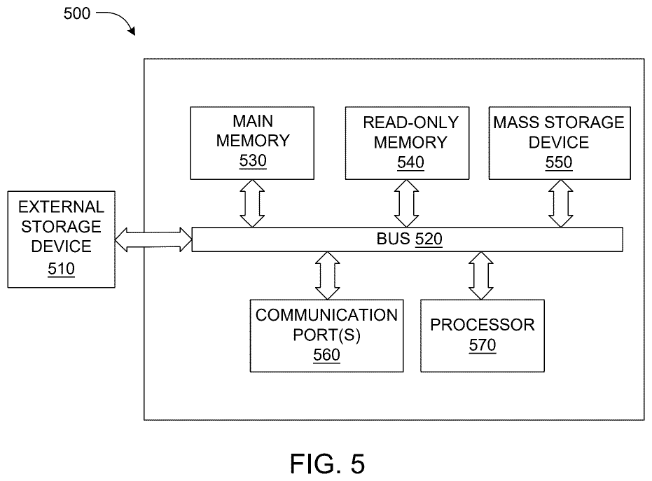

FIG. 5 illustrates an exemplary computer system (500) in which or with which embodiments of the present disclosure may be implemented. As shown in FIG. 5, the computer system (500) may include an external storage device (510), a bus (520), a main memory (530), a read only memory (540), a mass storage device (550), a communication port (560), and a processor (570). A person skilled in the art will appreciate that the computer system (500) may include more than one processor (570) and communication ports (560). Processor (570) may include various modules associated with embodiments of the present disclosure.

In an embodiment, the communication port (560) may be any of an RS-232 port for use with a modem-based dialup connection, a 10/100 Ethernet port, a Gigabit or 10 Gigabit port using copper or fiber, a serial port, a parallel port, or other existing or future ports. The communication port (560) may be chosen depending on a network, such a Local Area Network (LAN), Wide Area Network (WAN), or any network to which the computer system (500) connects.

In an embodiment, the memory (530) may be Random Access Memory (RAM), or any other dynamic storage device commonly known in the art. Read-only memory (540) may be any static storage device(s) e.g., but not limited to, a Programmable Read Only Memory (PROM) chips for storing static information e.g., start-up or Basic Input/Output System (BIOS) instructions for the processor (570).

In an embodiment, the mass storage device (550) may be any current or future mass storage solution, which may be used to store information and/or instructions. Exemplary mass storage solutions include, but are not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), one or more optical discs, Redundant Array of Independent Disks (RAID) storage, e.g., an array of disks (e.g., SATA arrays).

In an embodiment, the bus (520) communicatively couples the processor(s) (570) with the other memory, storage and communication blocks. The bus (520) may be, e.g., a Peripheral Component Interconnect (PCI)/PCI Extended (PCI-X) bus, Small Computer System Interface (SCSI), Universal Serial Bus (USB) or the like, for connecting expansion cards, drives and other subsystems as well as other buses, such a front side bus (FSB), which connects the processor (570) to the computer system (500).

Optionally, operator and administrative interfaces, e.g., a display, keyboard, joystick, and a cursor control device, may also be coupled to the bus (520) to support direct operator interaction with the computer system (500). Other operator and administrative interfaces may be provided through network connections connected through the communication port (560). Components described above are meant only to exemplify various possibilities. In no way should the aforementioned exemplary computer system (500) limit the scope of the present disclosure.

While the foregoing describes various embodiments of the present disclosure, other and further embodiments of the present disclosure may be devised without departing from the basic scope thereof. The scope of the present disclosure is determined by the claims that follow. The present disclosure is not limited to the described embodiments, versions or examples, which are included to enable a person having ordinary skill in the art to make and use the present disclosure when combined with information and knowledge available to the person having ordinary skill in the art.

### ADVANTAGES OF THE PRESENT DISCLOSURE

The present disclosure monitors Radio Frequency (RF) chain performance and Voltage Standing Wave Ratio (VSWR)-related issues in a cost-effective manner.

The present disclosure enables real-time monitoring of VSWR levels without a need of any external measurement device.

The present disclosure continuously analyses the reflected power and impedance matching within the radio system.

The present disclosure detects and identifies potential VSWR anomalies that may lead to signal degradation or equipment failure in advance.

The present disclosure improves performance and reliability of the radio system.

The present disclosure ensures optimal radio system performance in a cost-effective manner.

The present disclosure reduces operating expenses or expenditure (OPEX) cost and failure turnaround time of operators.

We claim:

1. A method for performing monitoring of voltage standing wave ratio (VSWR) in a radio system (200), the method comprising:
capturing a feedback digital pre-distortion (DPD) power from a DPD application at an application specific integrated circuit (ASIC)/a digital front end (DFE) (230);
calculating a transmit power at an antenna port (214) by adding a transmit power factor and the DPD feedback power;
reading a radio frequency (RF) power detector voltage output of a power detector circuitry (232) received via an on-board coupler (222) and a pi-PAD;
converting the RF power detector voltage output into an ADC value by an analog to digital converter (ADC) (234);
detecting whether the ADC value is valid;
on detecting that the ADC value is valid, calculating power detected at the power detector circuitry (232), wherein on detecting that the ADC value is not valid, reading the radio frequency (RF) power detector voltage output at the power detector circuitry (232);
calculating a reflected power at the antenna port (214) by adding a reflected power factor and the power detected at the power detector circuitry (232);
calculating a return loss at the antenna port (214);
detecting whether the return loss is equal to or less than zero; and
on detecting that the return loss is equal to or less than zero, calculating a reflection coefficient and the VSWR.

2. The method claimed as in claim 1, wherein the return loss is difference between the transmitted power and the reflected power at the antenna port (214).

3. The method claimed as in claim 1, wherein the DPD application is configured to:
characterize distortion by analyzing output of a power amplifier (PA) (206); and
alter an input signal to the PA (206).

4. The method claimed as in claim 1, wherein on detecting that the return loss is not equal to or less than zero, the method comprising performing of monitoring of VSWR.

5. The method claimed as in claim 1, wherein the transmit power calculation factor is calculated for each of plurality of transmit chains based on difference between the DPD feedback power received at the ADC of the ASIC/DFE and the transmitted power received at the antenna port (214).

6. A system for performing monitoring of voltage standing wave ratio (VSWR) in a radio system comprising an application specific integrated circuit (ASIC)/a digital front end (DFE) (230), a transceiver chain (228), a cavity filter (212), and a radio frequency (RF) antenna port (214);
the ASIC/DFE (230) having a digital pre-distortion (DPD) application configured to capture a DPD feedback power;
the RF antenna port (214) configured to calculate a transmit power by adding a transmit power factor and the DPD feedback power;
an analog to digital converter (ADC) (234) of the transceiver chain configured to read a radio frequency (RF) power detector voltage output received at a power detector circuitry (232) via an on-board coupler (222) and a pi-PAD;
the ADC (234) of the transceiver chain configured to convert the RF power detector voltage output into an analog value;
the ASIC/DFE (230) configured to detect whether an ADC value is valid;
on detecting that the ADC value is valid, the ASIC/DFE (230) configured to calculate power detected at the power detector circuitry (232), wherein on detecting that the ADC value is not valid, the power detector circuitry (232) configured to read the radio frequency (RF) power detector voltage output;
the ASIC/DFE (230) configured to calculate a reflected power by adding a reflected power factor and the power detected at the power detector circuitry (232);
the ASIC/DFE (230) configured to calculate a return loss;
the ASIC/DFE (230) configured to detect whether the return loss is equal to or less than zero; and
on detecting that the return loss is equal to or less than zero, the ASIC/DFE (230) configured to calculate a reflection coefficient and the VSWR.

7. The system claimed as in claim 6, wherein the return loss is difference between the transmitted power and the reflected power at the antenna port.

8. The system claimed as in claim 6, wherein on detecting that the return loss is not equal to or less than zero, the system configured to perform monitoring of VSWR.

9. The system claimed as in claim 6, wherein the transmit power calculation factor is calculated for each of plurality of transmit chains based on difference between the DPD feedback power received at the ADC (220) of the ASIC/DFE (230) and the transmitted power received at the antenna port (214).

10. The system claimed as in claim 6, wherein the transceiver chain (228) comprises a transmission chain, a feedback chain, and a receiver chain, wherein
the transmission chain comprises a first filter (202), a first digital step attenuator (DSA), a pre-driver, a power amplifier (206), a coupler (208) and a circulator (210);
the feedback chain comprises a filter (216) and a first Pi-PAD and
the receiver chain comprises a second PI-PAD, a single pole double throw (SPDT), a gain block, a second DSA, a second filter, a third SPDT, a low noise amplifier and the on-board coupler (222).

11. An apparatus for performing monitoring of voltage standing wave ratio (VSWR), the apparatus comprising an on-board coupler (222), a radio frequency (RF) power detector (232), and an analog-to-digital converter (ADC) (234);
the on-board coupler (222) configured to receive power reflected at an antenna port;
the RF power detector (232) configured to calculate received power via the on-board coupler;
the RF power detector (232) configured to translate the calculated power into analog voltage;
the ADC (234) configured to convert the analog voltage to digital voltage signal; and
the ADC (234) configured to send the digital voltage signal to an application specific integrated circuit (ASIC)/a digital front end (DFE) (230).

12. The apparatus claimed as in claim 11, wherein calculating a transmitted power at the antenna port (214) comprising:
a signal analyser configured to measure a digital pre-distortion (DPD) feedback power;
the signal analyser configured to calculate transmit power calculation factor for each of plurality of transmit chains based on difference between the DPD feedback power received at an ADC of the ASIC/DFE (230) and the transmitted power received at the antenna port (214); and
the signal analyser configured to calculate the transmitted power at the antenna port (214) based on the DPD power and the transmit power calculation factor.

13. The apparatus claimed as in claim 11, wherein calculating a reflected power at the antenna port (214) comprising:
the signal analyser configured to calculate reflected power calculation factor for each of plurality of receive chains based on insertion loss between the antenna port (214) to the RF power detector (232); and
the signal analyser configured to calculate the reflected power at the antenna port (214) based on the received power at the RF power detector (232) and the reflected power calculation factor.

14. The apparatus claimed as in claim 11, wherein calculating a return loss at the antenna port comprising:
the ASIC/the DFE (230) configured to calculate the return loss at the antenna port (214) is difference between the reflected power and the transmitted power at the antenna port (214).

15. The apparatus claimed as in claim 11, wherein calculating VSWR comprising:
the ASIC/the DFE (230) configured to calculate a reflection coefficient based on the return loss at the antenna port (214); and
the ASIC/the DFE (230) configured to calculate VSWR based on the reflection coefficient.

16. A computer program product comprising a non-transitory computer-readable medium comprising instructions that, when executed by one or more processors, cause the one or more processors to perform a method for performing monitoring of voltage standing wave ratio (VSWR) in a radio system, the method comprising:
capturing a feedback digital pre-distortion (DPD) power from a DPD application at an application specific integrated circuit (ASIC)/a digital front end (DFE) (230);
calculating a transmit power at an antenna port (214) by adding a transmit power factor and the DPD feedback power;
reading a radio frequency (RF) power detector voltage output of a power detector circuitry (232) received via an on-board coupler (222) and a pi-PAD;
converting the RF power detector voltage output into an ADC value by an analog to digital converter (ADC) (234);
detecting whether the ADC value is valid;
on detecting that the ADC value is valid, calculating power detected at the power detector circuitry (232), wherein on detecting that the ADC value is not valid, reading the radio frequency (RF) power detector voltage output at the power detector circuitry (232);
calculating a reflected power at the antenna port (214) by adding a reflected power factor and the power detected at the power detector circuitry (232);
calculating a return loss at the antenna port (214);
detecting whether the return loss is equal to or less than zero; and
on detecting that the return loss is equal to or less than zero, calculating a reflection coefficient and the VSWR.
